(19) United States
(12) Patent Application Publication
(10) Pub. No.: US 2018/0337657 A1
(43) Pub. Date: Nov. 22, 2018

(54) ACOUSTIC WAVE RESONATOR HAVING ANTIRESONANT CAVITY

(71) Applicant: Avago Technologies General IP (Singapore) Pte. Ltd., Singapore (SG)

(72) Inventors: Richard C. Ruby, Menlo Park, CA (US); Stephen Roy Gilbert, San Francisco, CA (US); Aleh S. Loseu, Santee, CA (US); Jalal Naghsh Nilchi, San Jose, CA (US)

(21) Appl. No.: 16/050,766

(22) Filed: Jul. 31, 2018

Related U.S. Application Data
(63) Continuation-in-part of application No. 14/866,394, filed on Sep. 25, 2015.

(51) Int. Cl. H03H 9/54; H03H 9/02; H03H 9/25; H03H 9/64

(52) U.S. Cl. CPC H03H 9/54; H03H 9/02574; H03H 9/02614; H03H 9/64; H03H 9/25

(57) ABSTRACT

An acoustic resonator filter comprises a plurality of resonator structures. One or more of the plurality of resonator structures comprises a substrate having a first surface and a second surface. The resonator structure also comprises a piezoelectric layer disposed over the substrate. The acoustic wave resonator structure also comprises a layer disposed between the first surface of the substrate and the second surface of the piezoelectric layer. The layer has a first surface and a second surface. The layer and the piezoelectric layer have a combined thickness (H) selected so an anti-resonance (AR) condition exists for an undesired bulk vertical shear mode between the first surface of the piezoelectric layer and the second surface of the layer.

### CROSS-REFERENCE TO RELATED APPLICATIONS

The present application is a continuation-in-part under 37 C.F.R. § 1.53(b) of, and claims priority under 35 U.S.C. § 120 from, U.S. patent application Ser. No. 14/866,394 filed on Sep. 25, 2015, naming Stephen Roy Gilbert, et al. as inventors. The entire disclosure of U.S. patent application Ser. No. 14/866,394 is specifically incorporated herein by reference.

### BACKGROUND

Electrical resonators are widely incorporated in modern electronic devices. For example, in wireless communications devices, radio frequency (RF) and microwave frequency resonators are used in filters, such as filters having electrically connected series and shunt resonators forming ladder and lattice structures. The filters may be included in a duplexer (diplexer, triplexer, quadplexer, quintplexer, etc.) for example, connected between an antenna (there could be several antennas like for MIMO) and a transceiver for filtering received and transmitted signals.

Various types of filters use mechanical resonators, such as acoustic wave resonators. The resonators convert electrical signals to mechanical signals or vibrations, and/or mechanical signals or vibrations to electrical signals.

While certain surface modes are desired, certain unwanted modes can exist between the opposing faces of the piezoelectric material of the acoustic wave resonator. These unwanted modes are parasitic, and can impact the performance of filters comprising acoustic wave resonators.

What is needed, therefore, is an acoustic wave resonator structure that overcomes at least the shortcomings of known acoustic wave resonators described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals, refer to like elements.

FIG. 1A is a top view of an acoustic wave resonator structure according to a representative embodiment.

FIG. 1B is a graph of admittance versus frequency.

FIG. 1C is the cross-sectional view of an acoustic wave resonator structure of FIG. 1A along line 1C-1C.

FIG. 2 is a simplified schematic block diagram of a filter comprising an acoustic wave resonator structure according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification, the appended claims, and during prosecution, and in addition to their ordinary meaning, the terms below are defined as follows:

‘Approximately’ means to within an acceptable limit or amount to one having ordinary skill in the art. For example, ‘approximately the same’ means that one of ordinary skill in the art would consider the items being compared to be the same; and

Relative terms, such as “above,” “below,” “beneath,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

In accordance with a representative embodiment, an acoustic wave resonator structure comprises substrate having a first surface and a second surface. The acoustic wave resonator structure also comprises a piezoelectric layer disposed over the substrate. The piezoelectric layer has a first surface, and a second surface. The second surface of the piezoelectric layer comprises a plurality of features. A plurality of electrodes is disposed over the first surface of the piezoelectric layer. The plurality of electrodes is configured to generate surface acoustic waves in the piezoelectric layer. The acoustic wave resonator structure also comprises a layer disposed between the first surface of the substrate and the second surface of the piezoelectric layer. The layer has a first surface and a second surface. The second surface of the layer is in contact with the second surface of the substrate, and has a smoothness sufficient to foster atomic bonding between the second surface of the layer and the first surface of the substrate. The layer and the piezoelectric layer have a combined thickness (H) selected so an anti-resonance (AR) condition exists layer for an undesired bulk vertical shear mode between the first surface of the piezoelectric layer and the second surface of the.

In accordance with another representative embodiment, a acoustic wave resonator filter comprises a plurality of acoustic wave resonator structures. One or more of the plurality of acoustic wave resonator structures comprises a substrate having a first surface and a second surface. The acoustic wave resonator structure also comprises a piezoelectric layer disposed over the substrate. The piezoelectric layer has a first surface, and a second surface, comprising a plurality of features. A plurality of electrodes is disposed over the first surface of the piezoelectric layer. The plurality of electrodes is configured to generate surface acoustic waves in the piezoelectric layer. The acoustic wave resonator structure also comprises a layer disposed between the first surface of the substrate and the second surface of the piezoelectric layer. The layer has a first surface and a second surface. The second surface of the layer is in contact with the second surface of the substrate, and has a smoothness sufficient to foster atomic bonding between the second surface of the layer and the first surface of the substrate. The layer and the piezoelectric layer have a combined thickness (H) selected so an anti-resonance (AR) condition exists for an undesired bulk vertical shear mode between the first surface of the piezoelectric layer and the second surface of the layer.

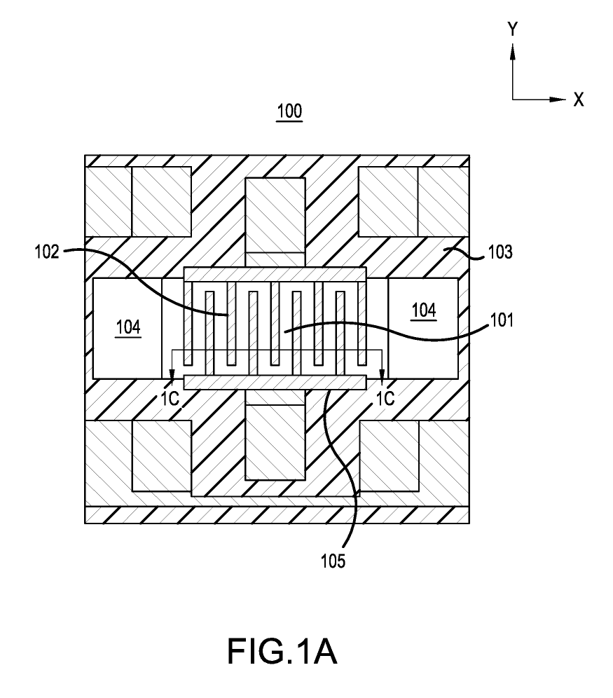

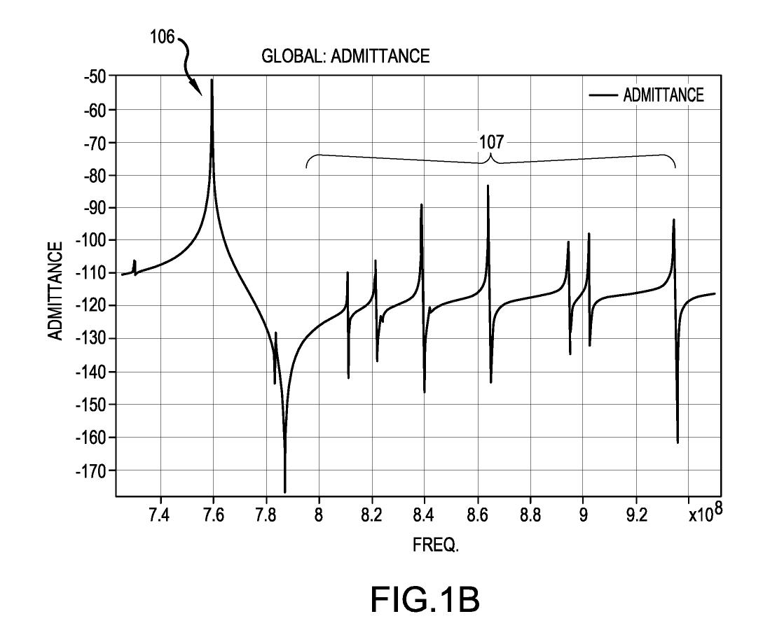

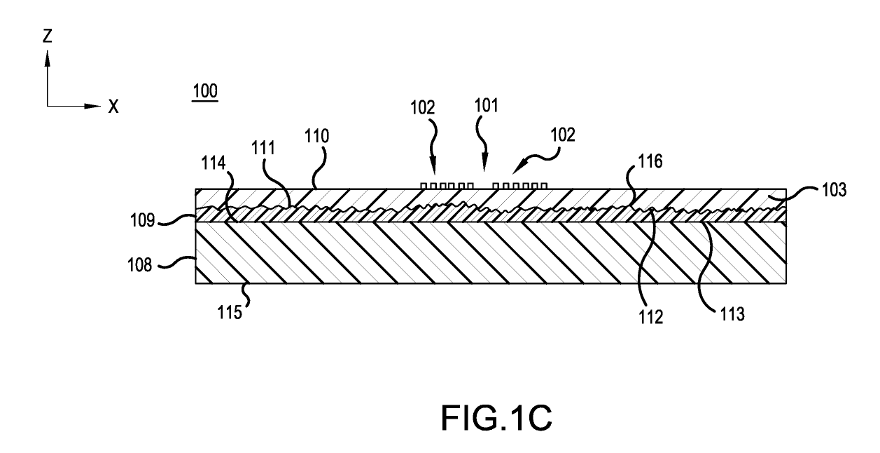

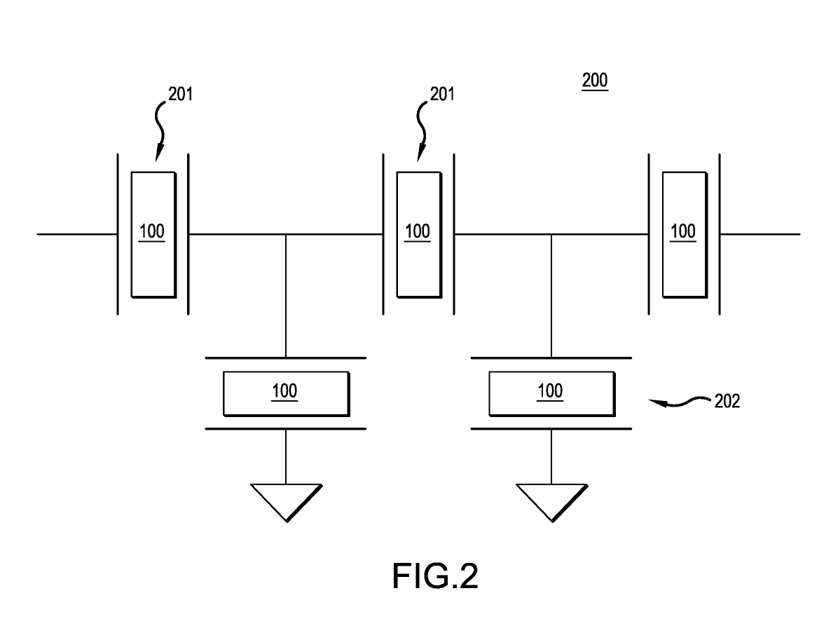

FIG. 1A is a top view of an acoustic wave resonator structure 100 according to a representative embodiment. Notably, the acoustic wave resonator structure 100 is intended to be merely illustrative of the type of device that can benefit from the present teachings. Other types of acoustic wave resonators, including, but not limited to dual mode acoustic wave resonators, and structures therefor, are contemplated by the present teachings. The acoustic wave resonator structure 100 of the present teachings is contemplated for a variety of applications. By way of example, and as described in connection with FIG. 2, a plurality of acoustic wave resonator structures 100 can be connected in a series/shunt arrangement to provide a ladder filter.

The acoustic wave resonator structure 100 comprises a piezoelectric layer 103 disposed over a substrate (not shown in FIG. 1A). In accordance with representative embodiments, the piezoelectric layer 103 comprises one of: lithium niobate (LiNbO₃), which is commonly abbreviated as LN; or lithium tantalate (LiTaO₃), which is commonly abbreviated as LT.

The acoustic wave resonator structure 100 comprises an active region 101, which comprises a plurality of IDTs 102 disposed over a piezoelectric layer 103, with acoustic reflectors 104 situated on either end of the active region 101. In the presently described representative embodiment, electrical connections are made to the acoustic wave resonator structure 100 using the busbar structures 105.

As is known, the pitch of the resonator electrodes (i.e., IDTs 102) determines the resonance conditions, and therefore the operating frequency of the acoustic wave resonator structure 100. Specifically, the IDTs 102 are arranged with a certain pitch between them, and a surface acoustic wave is excited most strongly when its wavelength λ is twice the pitch of the electrodes. The equation f₀=v/λ describes the relation between the resonance frequency (f₀), which is generally the operating frequency of the acoustic wave resonator structure 100, the propagation velocity (v), and wavelength λ of a surface acoustic wave. These acoustic wave waves comprise Rayleigh or Leaky waves, as is known to one of ordinary skill in the art, and form the basis of function of the acoustic wave resonator structure 100.

Generally, there is a desired fundamental mode, which is typically a Leaky mode, for the acoustic wave resonator structure 100. By way of example, if the piezoelectric layer 103 is a 42° rotated LT, the shear horizontal mode will have a displacement in the plane of interdigitated electrodes (IDTs) 102 (the x-y plane of the coordinate system of FIG. 1A). The displacement of this fundamental mode is substantially restricted to near the upper surface (first surface 110 as depicted in FIG. 1C) of the piezoelectric layer 103. It is emphasized that the 42° rotated LT piezoelectric layer 103, and the shear horizontal mode are merely illustrative of the piezoelectric layer 103 and desired fundamental mode, and other materials and desired fundamental modes are contemplated.

However, other, undesired modes, which may be referred to as spurious modes, are established. One such undesired mode is a bulk vertical shear mode that can be generated in the piezoelectric layer 103, and is found to have a wavelength related to the pitch of the IDTs 102. As described more fully below, in known acoustic wave resonators this vertical bulk shear mode is not confined to the resonance cavity defined by the reflectors on each end of the IDTs and the piezoelectric layer. This vertical bulk shear mode resonates, and undesired acoustic energy loss, if unmitigated, occurs. Ultimately, this results in a deterioration of the Quality factor (Q), which is manifest in an unacceptable roll off on the high frequency side of the transmission band of a filter (e.g., as shown in FIG. 3) comprising acoustic wave resonator structures 100.

Other spurious modes are also launched in the acoustic wave resonator structure, and are mitigated by one of a variety of structures described herein. Further details of acoustic wave structures with useful components to the present teachings are disclosed in commonly owned U.S. Patent Application Publication Nos.: 20180034440, 20180034439, 20170310304, 20170302251, 20170250673, 20170155373, 20170085247, 20170063339, 20170063338, 20170063333, 20170063332, 2017006331, and 20170063330. The entire disclosures of these identified commonly owned U.S. patent application Publications are specifically incorporated herein by reference.

Turning to FIG. 1B, a graph of admittance versus frequency is depicted for the illustrative 42° rotated LT piezoelectric layer 103. The desired fundamental mode, the shear horizontal mode 106, is substantially restricted to the upper surface of the piezoelectric layer 103, and has a frequency at series resonance (Fₛ). However, a number spurious modes 107, having frequencies greater than the frequency at parallel resonance (Fₚ), can exist in the piezoelectric layer 103. As described more fully below, these spurious modes 107 are created by acoustic waves generated in the piezoelectric layer 103 that establish standing waves of various kinds of modes (with different modal shapes and frequencies). More specifically, these spurious modes 107 are created by reflections at the interface of the piezoelectric layer 103 and the layer (see FIG. 1C) between the piezoelectric layer 103 and the substrate (see FIG. 1C) of the acoustic wave resonator structure 100.

The spurious modes can deleteriously impact the performance of acoustic wave resonators, and devices (e.g., filters) that include acoustic wave resonators, if not mitigated. Most notably, if a first filter is comprised of one or more acoustic wave resonators, and is connected to a second filter having a passband that overlaps the frequency of the spurious modes, a sharp reduction in the quality (Q) of the second filter will occur. The spurious modes are observed on a so-called Q-circle of a Smith Chart of the S₁₁ parameter. These sharp reductions in Q-factor are known as “rattles,” and are strongest in the southeast quadrant of the Q-circle. Beneficially, significant mitigation of the adverse impact of these spurious modes is realized by the various aspects of the present teachings as described below.

FIG. 1C is a cross-sectional view of the acoustic wave resonator structure 100 depicted in FIG. 1A along the lines 1B-1B. The acoustic wave resonator structure 100 comprises a substrate 108 disposed beneath the piezoelectric layer 103, and a layer 109 disposed between the substrate 108 and the piezoelectric layer 103.

As noted above, the piezoelectric layer 103 illustratively comprises one of LN or LT. Generally, in the representative embodiments described below, the piezoelectric layer 103 is a wafer that is previously fabricated, and that is adhered to the substrate 108 by atomic bonding with the layer 109 as described more fully below.

The materials selected for the piezoelectric layer 103 can be divided into two types: one which has been used for a long time and with a high degree of freedom in design is used for Rayleigh wave substrates; the other, with less freedom and limited in design, is for Leaky wave substrates with low loss characteristics and easily reaches the higher frequencies by high acoustic velocity, and are mainly used for mobile communications. LN and LT materials are often used for broadband filters, and according to the filter specifications, the manufacturing materials and cutting angles differ. Filters for applications that require comparatively low loss mainly generally require Leaky wave materials, while Rayleigh wave materials are predominately used for communication equipment that requires low ripple and low group delay characteristics. Among Rayleigh wave materials, ST-cut crystal has the best temperature characteristics as a piezoelectric material. Moreover, Applicants have discovered that as the LT cut angle is increased from 42° to 46.3°, or even to 48°, the performance of the acoustic wave resonators and filter comprising acoustic wave resonators become less dependent on the thickness of the (LT) piezoelectric layer 103. This is desirable for integrating multiple filters on a die because optimum LT thickness is dependent on filter frequency. Reducing the dependence of the (LT) piezoelectric layer 103 on thickness also helps with substrate process control.

In accordance with a representative embodiment, the substrate 108 comprises crystalline silicon, which may be polycrystalline or monocrystalline, having thickness of approximately 100.0 μm to approximately 800.0 μm. Other polycrystalline or monocrystalline materials besides silicon are contemplated for use as the substrate 108 of the acoustic wave resonator structure 100. By way of example, these materials include, but are not limited to, glass, single crystal aluminum oxide (Al₂O₃) (sometimes referred to as “sapphire”), and polycrystalline Al₂O₃, to name a few. In certain representative embodiments, in order to improve the performance of a filter comprising acoustic wave resonator structure(s) 100, the substrate 108 may comprise a comparatively high-resistivity material. Illustratively, the substrate 108 may comprise single crystal silicon that is doped to a comparatively high resistivity.

In some embodiments, the layer 109 is illustratively an oxide material, such as silicon dioxide (SiO₂), or phosphosilicate glass (PSG), borosilicate glass (BSG), a thermally grown oxide, or other material amenable to polishing to a high degree of smoothness, as described more fully below. The layer 109 is deposited by a known method, such as chemical vapor deposition (CVD) or plasma enhanced chemical vapor deposition (PECVD), or may be thermally grown. As described more fully below, the layer 109 is polished to a thickness in the range of approximately 0.05 μm to approximately 6.0 μm.

Other materials contemplated for use as the layer 109 include ZnO₂, HfO₂, AlN, Y₂O₃, Yb₂O₃, Cr₂O₃, Sc₂O₃, ZrO₂ and La₂O₃. Notably, acoustic waves travel at a high velocity compared to their velocity in the piezoelectric layer 103. This difference in acoustic velocity at the interface of the piezoelectric layer 103 and the layer 109 fosters a reduction in acoustic losses of the acoustic wave resonator structure 100. Generally, these other materials selected for layer 109 have an acoustic impedance in the range of acoustic impedance in the range of approximately 30 MRayls to approximately 50 MRayls; and/or the velocity of acoustic waves therein is in the range of approximately 4000 m/sec to approximately 15,000 m/s.

The substrate 108 has a first surface 114 and a second surface 115 opposing the first surface 114. In representative embodiments, the substrate 108 undergoes a chemical-mechanical polish (CMP) sequence to prepare the first surface to bond to the layer 109, as described below.

Layer 109 has a first surface 112 and a second surface 113. As noted above, the second surface 113 of layer 109 is polished, such as by chemical-mechanical polishing in order to obtain a “mirror” like finish with a comparatively low root-mean-square (RMS) variation of height. This low RMS variation of height significantly improves the contact area between the second surface 113 of the layer 109 and the first surface 114 of the substrate 108 to improve the atomic bonding between the first surface 114 and the second surface 113. As is known, the bond strength realized by atomic bonding is directly proportional to the contact area between two surfaces. As such, improving the flatness/smoothness of the second surface 113 fosters an increase in the contact area, thereby improving the bond of the layer 109 to the substrate 108. As used herein, the term “atomically smooth” means sufficiently smooth to provide sufficient contact area to provide a sufficiently strong bond strength between the layer 109 and the substrate 108, at the interface of their second and first surfaces 113, 114, respectively.

The piezoelectric layer 103 has a first surface 110, and a second surface 111, which opposes the first surface 110. The second surface 111 has a plurality of features 116 there-across. As noted above, undesired spurious modes are launched in the piezoelectric layer 103, and propagate down to the second surface 111.

Additionally, the undesired bulk vertical shear mode is supported by the (leaky) resonant cavity provided in the piezoelectric layer and the layer 109 subtended by the IDTs 102 (and air interface above the piezoelectric layer 103), and the first surface 114 of the substrate 108.

Often, the velocity of the undesired bulk vertical shear mode is approximately twice the velocity of the desired shear mode of the acoustic wave resonator structure 100. By way of illustration, to effect such a desired shear mode, the pitch of the IDTs is, in this illustrative example, 2.0 μm, which places the wavelength of the desired shear mode at 4.0 μm. Given this illustrative wavelength of the desired shear mode, the velocity of the undesired bulk vertical shear mode is twice that of the desired shear mode, and has a wavelength (in the piezoelectric layer 103 and the layer 109) of 8.0 μm. More generally, by this illustrative example, the wavelength λ_{d} of the desired shear mode is given by vₐ/fₛ, where vₐ is the velocity of the desired shear mode in the piezoelectric layer 103, and fₛ is the frequency of the desired shear mode in the piezoelectric layer 103. By this example, the wavelength of the undesired bulk vertical shear mode is given by λ_{b}=2λ_{d}. As such, an undesired bulk vertical shear mode traversing the thickness (z-direction in the coordinate system of FIG. 1C), is reflected at the interface of the piezoelectric layer 103 and the layer 109, and returns toward the side of the piezoelectric layer 103 over which the IDTs 102 are disposed. Such “a round trip” for the undesired bulk vertical shear mode results in a resonance condition if the combined thickness of the piezoelectric layer 103 and the layer 109 is ½ λ_{b} (or 4 μm in the present example). This structure can be described as a resonant cavity. Because the acoustic impedance of the substrate (108) is not infinite. Some amount of this ‘resonant’ energy leaks into the substrate and is lost, thereby degrading the overall Q. As can be appreciated, this parasitic bulk vertical shear mode is not desired, as it results in undesirable loss in Q.

However, by the present teachings, rather than selecting the combined thickness of the piezoelectric layer 103 and the layer 109 as an even multiple of ½ λ_{b} to establish a resonant cavity through the selection as an even multiple of ½ λ_{b}, the combined thickness (z-direction in the coordinate system of FIG. 1C) of the piezoelectric layer 103 and the layer 109 is selected to establish an anti-resonance (AR) condition (and thereby an AR cavity) for the undesired bulk vertical shear mode. The AR cavity for this undesired bulk vertical shear mode exists in the piezoelectric layer 103 and layer 109 subtended by the IDTs 102 (and air interface above the piezoelectric layer 103), and the first surface 114 of the substrate 108. This AR condition supports destructive interference at the wavelength (λ_{b}) of the undesired bulk vertical shear mode. Beneficially, therefore, by the present teachings, the undesired bulk vertical shear mode is not supported in the piezoelectric layer 103, and its deleterious impact is substantially avoided.

The establishment of anti-resonance for the undesired bulk vertical shear mode is established by selecting the combined thickness (H) of the piezoelectric layer 103 and the layer 109 to be odd multiples of 4/4 or odd multiples of λ_{d}/2. Stated in terms of the pitch (X) (where X=λ_{d}/2) of the IDTs 102, the AR condition to effect destructive interference can be expressed as nX where n is a positive odd integer. Notably, providing a thickness (z-dimension of the coordinate system of FIG. 1C) of n=1 or n=3 is often not practical, so in accordance with a representative embodiment, n=5, 7, 9, 11 . . . . In a representative embodiment, the maximum combined thickness (H) of the piezoelectric layer 103 and the layer 109 is the thickness of the substrate 108. As such, the odd positive integer n has an upper limit set by this maximum combined thickness.

Continuing the example above, the conditions for establishing AR harmonics would be 2.0 μm, 6.0 μm (i.e., 3/2λ_{b}), 10.0 μm (i.e., 5/2λ_{b}), 14.0 μm (i.e., 7/2λ_{b}), 10.0 μm (i.e., 9/2λ_{b}), etc. As such, ignoring the first two AR conditions due to practical fabrication issues, the thicknesses of the piezoelectric layer 103 to suppress the propagation of the undesired bulk vertical shear mode is 10 μm, 14 μm, 18 μm, 22 μm.

Notably, Applicants have determined a correction factor that improves the suppression of the undesired bulk vertical shear mode. The correction is also impacted by the relative acoustic velocities of the desired shear mode and the undesired bulk vertical shear mode. Just by way of example, if the acoustic velocity of the undesired bulk vertical shear mode were not exactly twice that of the desired shear mode, the correction factor would be adjusted accordingly. To this end, generally the correction factor is a ratio of the acoustic velocity of the undesired bulk vertical shear mode to the desired shear mode. As such, if the acoustic velocity of the undesired bulk vertical shear mode were twice that of the desired shear mode, the correction factor would be 2.0 By contrast of the acoustic velocity of the undesired bulk vertical shear mode were 1.5 times that of the desired shear mode the correction factor would be 1.5.

One measure of the impact of the parasitic spurious modes on the performance of a device (e.g., filter) comprising an acoustic wave resonator are spurious modes that ‘suck out’ energy from the main (desired) mode of the filter, or the main (desired) modes of other filters at different frequency bands connected at the antenna port. Multiple filters connected to a common antenna will suffer from spurious modes generated by the parasitic spurious modes. The loss in energy is manifest in a reduction of the S₁₁ parameter, and appear as ‘suck outs’ or “rattles.” The “rattles” are generally strongest above the passband. Beneficially, and in addition to the reduction in loss of energy to the undesired bulk vertical shear mode by the establishment of an AR cavity as described above, the plurality of features 116 foster diffuse reflections at the interface of the piezoelectric layer 103, and the layer 109, and attendant phase mismatch of the reflected acoustic waves realized by the plurality of features 116, compared to such known devices, a filter comprising acoustic wave resonator structure 100 of representative embodiments of the present teachings, shows significant reduction of the “rattles” and a somewhat “spreading” in frequency of the reduced “rattles” is experienced.

As noted above, when connected in a selected topology, a plurality of acoustic wave resonators can function as an electrical filter. FIG. 2 shows a simplified schematic block diagram of an electrical filter 200 in accordance with a representative embodiment. The electrical filter 200 comprises series acoustic wave resonators 201 and shunt acoustic wave resonators 202. The series acoustic wave resonators 201 and shunt acoustic wave resonators 202 may each comprise acoustic wave resonator structures 100 described in connection with the representative embodiments of FIGS. 1A-1C. As can be appreciated, the acoustic wave resonator structures (e.g., a plurality of acoustic wave resonator structures 100) that comprise the electrical filter 200 may be provided over a common substrate (e.g., substrate 108), or may be a number of individual acoustic wave resonator structures (e.g., acoustic wave resonator structures 100) disposed over more than one substrate (e.g., more than one substrate 108). The electrical filter 200 is commonly referred to as a ladder filter, and may be used for example in duplexer applications. It is emphasized that the topology of the electrical filter 200 is merely illustrative and other topologies are contemplated. Moreover, the acoustic resonators of the representative embodiments are contemplated in a variety of applications including, but not limited to duplexers.

Notably, in accordance with a representative embodiment, because of the reduction in energy loss to the undesired bulk vertical shear mode and spurious modes, an acoustic wave filter of has a roll-off at a high frequency side of a passband of approximately 0.5 to approximately 0.6 times a guard band. Moreover, an acoustic wave filter of the present teachings has a passband roll-off from approximately 2.5 dB to approximately 50 dB.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. An acoustic wave resonator structure, comprising:
substrate having a first surface and a second surface;
a piezoelectric layer disposed over the substrate, the piezoelectric layer having a first surface, and a second surface comprising a plurality of features;
a plurality of electrodes disposed over the first surface of the piezoelectric layer, the plurality of electrodes configured to generate surface acoustic waves in the piezoelectric layer; and
a layer disposed between the first surface of the substrate and the second surface of the piezoelectric layer, the layer having a first surface and a second surface, the second surface of the layer being on contact with the second surface of the substrate, and having a smoothness sufficient to foster atomic bonding between the second surface of the layer and the first surface of the substrate, wherein the layer and the piezoelectric layer have a combined thickness (H) selected so an anti-resonance (AR) condition exists between the first surface of the piezoelectric layer and the second surface of the layer for an undesired bulk vertical shear mode.

2. The acoustic wave resonator structure of claim 1, wherein a pitch of the plurality of electrodes is selected to be one-half of a wavelength (λ/2) of a desired resonant mode.

3. The acoustic wave resonator structure of claim 2, wherein the combined is equal to approximately to a correction factor (n) times the pitch of the plurality of electrodes, wherein n is an integer in the range of approximately 5 to approximately 20.

4. The acoustic wave resonator structure of claim 3, wherein the correction factor is a ratio of a velocity of the undesired bulk vertical shear mode in the piezoelectric layer to a velocity of the desired resonant mode.

5. The acoustic wave resonator structure as claimed in claim 1, wherein at least some of the plurality of features have substantially slanted sides.

6. The acoustic wave resonator structure as claimed in claim 5, wherein at least some of the plurality of features are substantially not in a regular pattern.

7. The acoustic wave resonator structure as claimed in claim 5, wherein the at least some of the plurality of features have a height of approximately one-fourth of a wavelength (¼λ) of a spurious mode.

8. The acoustic wave resonator structure as claimed in claim 5, wherein the at least some of the plurality of features have a plurality of heights, and each of the pluralities of heights is approximately a height in the range of approximately one-fourth of a wavelength (¼λ) of one of the plurality of spurious modes.

9. The acoustic wave resonator structure as claimed in claim 1, wherein the layer comprises an oxide material.

10. The acoustic wave resonator structure as claimed in claim 9, wherein the oxide material comprises silicon dioxide (SiO₂).

11. The acoustic wave resonator structure as claimed in claim 10, wherein the second surface of the layer has a root-mean-square (RMS) variation in height of approximately 0.1 Å to approximately 10.0 Å.

12. The acoustic wave resonator structure as claimed in claim 1, wherein the layer comprises one of ZnO₂, HfO₂, AlN, Y₂O₃, Yb₂O₃, Cr₂O₃, Sc₂O₃.

13. An acoustic wave filter comprising a plurality of acoustic wave resonator structures, one or more of the plurality of acoustic wave resonator structures comprising:
substrate having a first surface and a second surface;
a piezoelectric layer disposed over the substrate, the piezoelectric layer having a first surface, and a second surface, comprising a plurality of features;
a plurality of electrodes disposed over the first surface of the piezoelectric layer, the plurality of electrodes configured to generate surface acoustic waves in the piezoelectric layer; and
a layer disposed between the first surface of the substrate and the second surface of the piezoelectric layer, the layer having a first surface and a second surface, the second surface of the layer being on contact with the second surface of the substrate, and having a smoothness sufficient to foster atomic bonding between the second surface of the layer and the first surface of the substrate, wherein the layer and the piezoelectric layer have a combined thickness (H) selected so an anti-resonance (AR) condition exists between exists between the first surface of the piezoelectric layer and the second surface of the layer for an undesired bulk vertical shear mode.

14. The acoustic wave filter of claim 13, wherein the acoustic wave filter has a roll-off at a high frequency side of a passband of approximately 0.5 to approximately 0.6 times a guard band.

15. The acoustic wave filter of claim 14, wherein the passband rolls off from approximately 2.5 dB to approximately 50 dB.

16. The acoustic wave filter of claim 13, wherein the pitch is selected to be one-half of a wavelength (λ/2) of a desired resonant mode.

17. The acoustic wave filter of claim 16, wherein the combined thickness is equal to approximately to a correction factor (n) times the pitch of the plurality of electrodes, wherein n is an integer in the range of approximately 5 to approximately 20.

18. The acoustic wave filter of claim 17, wherein the correction factor is a ratio of a velocity of the undesired bulk vertical shear mode in the piezoelectric layer to a velocity of the desired resonant mode.

19. A acoustic wave filter as claimed in claim 13, wherein at least some of the plurality of features in the first surface of the substrate have substantially slanted sides.

20. A acoustic wave filter as claimed in claim 13, wherein the plurality of features are substantially not in a regular pattern.
